(19) United States
(12) Patent Application Publication
(10) Pub. No.: US 2015/0259822 A1
(43) Pub. Date: Sep. 17, 2015

(54) APPARATUS FOR MANUFACTURING INGOT

(71) Applicants: Hyun Goo Kwon, Uiwang (KR); Yeo Kyun Yoon, Hwaseong (KR); Min Soo Son, seoul (KR)

(72) Inventors: Hyun Goo Kwon, Uiwang (KR); Yeo Kyun Yoon, Hwaseong (KR); Min Soo Son, seoul (KR)

(73) Assignee: TECHNOVALUE CO., LTD., Seoul (KR)

(21) Appl. No.: 14/257,185

(22) Filed: Apr. 21, 2014

(30) Foreign Application Priority Data
Mar. 14, 2014 (KR) 10-2014-0030660

(51) Int. Cl. C30B 15/00

(52) U.S. Cl. CPC C30B 15/002

(57) ABSTRACT

There is disclosed an apparatus for manufacturing an ingot, which supplies silicon intermittently or continuously while the ingot is growing, the apparatus including a crucible having a melting zone in which silicon melted, an inner wall having a growth zone in which the ingot grows from the molten silicon supplied from the crucible, a sweeping gas supply unit configured to supply sweeping gas to the growth zone, and a passage unit configured to provide a passage of the sweeping gas transferred outside the crucible, the passage unit comprising an upper heat shield configured to cover an upper portion of the melting zone and a sweeping wall extended from the upper heat shield toward the melting zone in a downward direction.

### TECHNICAL FIELD

The present invention relates to apparatus for manufacturing an ingot.

### BACKGROUND

An ingot is important in the manufacture of a semiconductor chip or a solar cell. The ingot is manufactured during a process of melting and solidifying silicon in a crucible.

The ingot is manufactured by Czochralski method in which, while a rod or a seed crystal which has penetrated molten silicon is slowly lifted, the silicon attached in the vicinity of the rod or seed crystal is solidified.

FIG. 1 is a diagram schematically illustrating a conventional continuous type ingot manufacturing apparatus.

As shown in FIG. 1, a sweeping gas (I) is injected toward an ingot (IG) and transferred along a lower portion of an upper heat shield 310, passing a growth zone (GZ) in which an ingot grows. After that, the sweeping gas is exhausted outside.

However, there could be a wide space formed between a surface of a melting zone (MZ), in which silicon is melted, and the upper heat shield 310 in the conventional continuous type ingot manufacturing apparatus. Accordingly, a velocity of sweeping gas flow in an upper portion of the melting zone (MZ) might be lowered and a vortex of the sweeping gas might be generated. Such a vortex could cause failure in smooth exhaustion of silicon oxide dust.

In addition, the conventional continuous type ingot manufacturing apparatus could have a disadvantage that the sweeping gas (I) fails to sweep the surface of the melting zone (MZ) effectively and fails to remove the silicon oxide generated in a surface of the melting zone (MZ) smoothly.

### Technical Problem

To solve the problems, an object of the disclosure is to provide an apparatus for manufacturing an ingot (hereinafter, an ingot manufacturing apparatus) which can prevent dust from being drawn into a growth zone.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

### Technical Solution

To achieve these objects and other advantages and in accordance with the purpose of the embodiments, as embodied and broadly described herein, an apparatus for manufacturing an ingot, which intermittently or continuously supplies the silicon while the ingot is growing, includes a crucible having a melting zone in which silicon melted; an inner wall having a growth zone in which the ingot grows from the molten silicon supplied from the crucible; a sweeping gas supply unit configured to supply sweeping gas to the growth zone; and a passage unit configured to provide a passage of the sweeping gas transferred outside the crucible, the passage unit comprising an upper heat shield configured to cover an upper portion of the melting zone and a sweeping wall extended from the upper heat shield toward the melting zone in a downward direction.

The passage may include a first part passage formed between the inner wall and the sweeping wall; a second part passage formed between a surface of the melting zone and the sweeping wall; a third part passage formed between the sweeping wall and the crucible; and a fourth part passage formed between the upper heat shield and an upper end of the crucible.

The third part passage may be smaller than or the same as the second part passage.

A cross sectional area of the sweeping wall may be increased more and more along the downward direction.

The sweeping wall may be getting closer to the inner wall along the downward direction.

The sweeping wall may be getting closer to the crucible along the downward direction.

A cross sectional area of the sweeping wall may be increased more and more along an upward direction to the upper heat shield.

The passage unit may include an auxiliary sweeping wall provided under the upper heat shield in the fourth part passage.

The fourth part passage may be getting narrower along a direction in which the sweeping gas is transferred.

A height to a lower end of the sweeping wall from a surface of the melting zone may be smaller than a height to an upper end of the inner wall from a surface of the melting zone.

A height to a lower end of a side portion of the sweeping wall facing the inner wall from a surface of the melting zone may be larger than a height to a lower end of the other side portion of the sweeping wall facing the crucible from a surface of the melting zone.

A height to a lower end of a side portion of the sweeping wall facing the inner wall may be smaller than a height to a lower end of the other side portion of the sweeping wall facing the crucible from a surface of the melting zone.

The apparatus for manufacturing the ingot may further include a feeding unit configured to supply silicon to the melting zone via a silicon supply hole formed in the sweeping wall, wherein an end of the feeding unit and a lower end of the sweeping wall are located on the same plane.

The sweeping wall may be formed of a material selected from the group consisting of graphite, SiC, SiN, SiCN, SiBN, SicBN, ZrC, ZrN, ZrCN, ZrBN, ZrcBN, TiC, TiN, TiCN, TiBN, TicBN, molybdenum, tungsten and tantalum.

A surface of the sweeping wall may be coated with a material selected from the group consisting of SiC, SiN, SiCN, SiBN, SicBN, ZrC, ZrN, ZrCN, ZrBN, ZrcBN, TiC, TiN, TiCN, TiBN and TicBN.

In another aspect, an apparatus for manufacturing an ingot, which intermittently or continuously supplies the silicon while the ingot is growing, includes a crucible having a melting zone in which silicon melted; an inner wall having a growth zone in which the ingot grows from the molten silicon supplied from the crucible; a sweeping gas supply unit configured to supply sweeping gas to the growth zone; and a passage unit comprising an upper heat shield configured cover an upper portion of the melting zone and a sweeping wall extended from the upper heat shield toward the melting zone in a downward direction, with a silicon supply hole configured to supply the silicon.

A height to a lower end of the sweeping wall may be smaller than a height to an upper end of the inner wall from a surface of the melting zone.

A height to a lower end of a side portion of the sweeping wall facing the inner wall may be larger than a height to a lower end of the other side portion of the sweeping wall facing the crucible from a surface of the melting zone.

The apparatus for manufacturing the ingot may further include a feeding unit configured to supply silicon to the melting zone via the silicon supply hole formed in the sweeping wall, wherein an end of the feeding unit and a lower end of the sweeping wall may be located on the same plane.

### Advantageous Effects

The embodiments have following advantageous effects. The flow of the transferred sweeping gas may be controlled and dust can be exhausted outside smoothly in the ingot manufacturing apparatus.

Furthermore, as the sweeping gas is flowing along the surface of the melting zone, the dust in the surface of the melting zone may be reduced.

The objectives and other advantages of the invention may be realized and attained by the structure particularly pointed out in the written description and claims hereof as well as the appended drawings.

### BRIEF DESCRIPTION OF THE DRAWINGS

The accompanying drawings, which are included to provide a further understanding of the disclosed subject matter and are incorporated in and constitute a part of this specification, illustrate exemplary embodiments of the disclosed subject matter, and together with the description serve to explain the principles of the disclosed subject matter.

FIG. 1 is a diagram schematically illustrating a conventional continuous type ingot manufacturing apparatus;

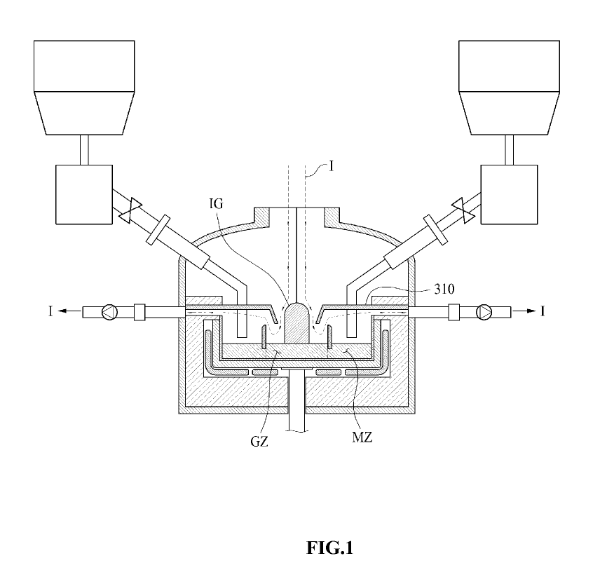

FIG. 2 is a diagram schematically illustrating an ingot manufacturing apparatus according to one embodiment of the disclosure;

FIG. 3 is a diagram schematically illustrating a passage of sweeping gas transferred via a passage unit;

FIG. 4 is a diagram schematically illustrating an ingot manufacturing apparatus according to another embodiment of the disclosure;

FIG. 5 is a diagram schematically illustrating an ingot manufacturing apparatus according to a further embodiment of the disclosure;

FIG. 6 is a diagram schematically illustrating an ingot manufacturing apparatus according to a still further embodiment of the disclosure; and

FIG. 7 is a diagram schematically illustrating an ingot manufacturing apparatus according to a still further embodiment of the disclosure.

### DETAILED DESCRIPTION

Hereinafter, exemplary embodiments of the disclosure will be described in detail, referring to the accompanying drawings. For the sake of brief description with reference to the drawings, the same or equivalent components will be provided with the same reference numbers, and description thereof will not be repeated.

The terminology used herein is for the purpose of describing exemplary embodiments only and is not intended to be limiting of the disclosed subject matter. As used herein, the singular forms “a”, “an”, and “the” are intended to include the plural forms as well, unless the context clearly indicates otherwise.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

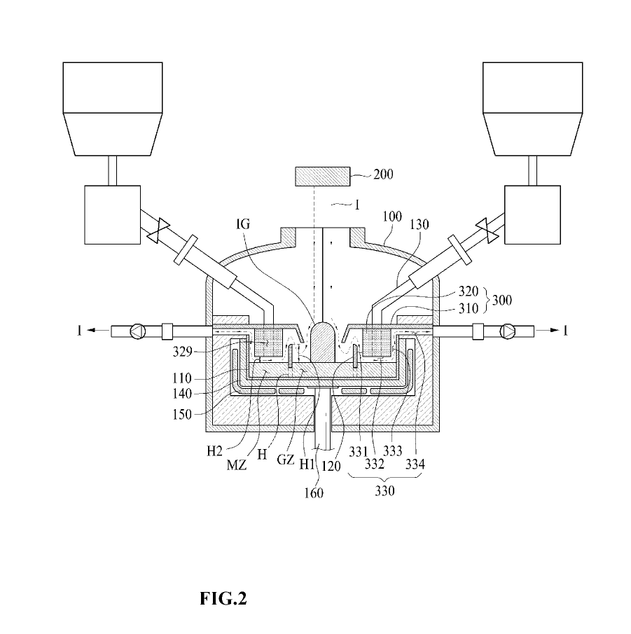

FIG. 2 is a diagram schematically illustrating an ingot manufacturing apparatus according to one embodiment of the disclosure. The apparatus according to the embodiment of the disclosure may be a continuous Czochralski type ingot manufacturing apparatus which can intermittently or continuously provide silicon while an ingot (IG) is growing.

As shown in FIG. 2, the ingot manufacturing apparatus according to the present embodiment may include a crucible 110, an inner wall 120, a feeding unit 130, a sweeping gas supply unit 200 and a passage unit 300.

The chamber 100 may provide a predetermined space in which silicon is melted and growing.

The crucible 110 may be mounted in the chamber 100 and it may have a melting zone (MZ) in which molten silicon is formed and a growth zone (GZ) in which an ingot (IG) is growing from the molten silicon. The melting zone (MZ) may be a region between the crucible 110 and an inner wall 120. The crucible 110 may be formed of quartz and the material of the crucible 110 is not limited to quartz. Diverse materials capable of bearing high temperatures, with less reactivity with the molten silicon may be used.

The inner wall 120 may be surrounded by the crucible 110. The growth zone (GZ) may be provided in the inner wall 120 and silicon or dopant melted in the crucible 110 may be drawn into the growth zone (GZ) to grow the ingot (IG). The inner wall may be also formed of quartz, like the crucible 110.

A feeding unit 130 may provide the melting zone (MZ) with the silicon.

The intermittent or continuous supply of the silicon may be controlled by a supply control unit configured to control the feeding unit 130. The feeding unit 130 may be a pipe or tube and the shape of the feeding unit is not limited thereto. The feeding unit 130 may pass through a passage unit 300 and detailed description of the passage unit will be provided later.

A susceptor 140 may surround the crucible 110. The growth of the ingot (IG) is performed at high temperatures such that the crucible 110 can get soft. The susceptor 140 may support the shape of the crucible 110.

A heater 150 may apply heat to the crucible 110 to melt the silicon provided from the feeding unit 130. The heater 150 may be provided adjacent to the susceptor 140.

The heater 150 may heat the silicon approximately to 1420° C. which is a melting temperature of the silicon, such that the silicon can be melted in the crucible 110. A dopant as well as the silicon may be introduced to the crucible 110. When the heater 150 is driven, the dopant may be melted together with the silicon. The dopant may be a trivalent or pentavalent material (e.g., phosphorus and boron) and the material is not limited thereto.

Such the molten silicon or dopant may be introduced into the growth zone (GZ) of the inner wall 120 via an inlet (H) formed in the inner wall 120. The molten silicon or dopant is gradually cooled provided in the growth zone, to be grown into the ingot (IG). At this time, the dopant may be distributed in the ingot (IG).

A shaft 160 may be connected to the susceptor 140 to rotate the susceptor 140. Along the rotation of the susceptor 140, the crucible 110 may be rotated in the same direction. The ingot (IG) may grow, while rotated in the reverse direction of the shaft 160.

The sweeping gas supply unit 200 may be installed in an outer portion of the chamber 100, to supply sweeping gas to the chamber 100. The sweeping gas supply unit 200 may supply the sweeping gas (I) to the growth zone (GZ).

The sweeping gas (I) may be Ar, He or nitrogen and examples of the sweeping gas are not limited thereto. Gases with less reactivity to silicon may be used.

The passage unit 300 may provide a passage along which the 0073weeping gas (I) is transferred outside the crucible 110. The passage unit 300 may include an upper heat shield 310 and a sweeping wall 320.

The upper heat shield 310 may cover an upper portion of the melting zone (MZ). The upper heat shield 310 shown in FIG. 2 may be extended from a lateral surface of the chamber 100 in a horizontal direction to cover the upper portion of the crucible 110.

The sweeping wall 320 may be extended from the upper heat shield 310 toward the melting zone downward. The sweeping wall 320 may be coupled to a lower end of the heat shield 310 and arranged between the crucible 110 and the inner wall 120.

The sweeping wall 320 may be a tube-shaped and the shape of the sweeping wall is not limited thereto. The sweeping wall 320 may be arranged in an upper portion of the melting zone (MZ).

A silicon supply hole 329 in communication with the feeding unit 130 may be formed in the sweeping wall 320. The silicon supplied from the feeding unit 130 may be introduced into the melting zone (MZ) via the silicon supply hole 329. The feeding unit 130 may be inserted in the silicon supply hole 329 formed in the sweeping wall 320. The feeding unit 130 may provide the melting zone (MZ) with the silicon via the silicon supply hole 329.

A height (H2) to a lower end of the sweeping wall 320 from a surface of the melting zone (MZ) may be smaller than a height (H1) to an upper end of the inner wall 120 from a surface of the melting zone (MZ).

Generally, dust drawn into the growth zone might hamper the growth of the ingot (IG). Especially, dust could be generated while the silicon is supplied to the melting zone (MZ) and the dust could be drawn into the growth zone (GZ),

However, the sweeping wall 320 applied in the present embodiment may form a narrow passage, together with the inner wall 120. So compared with the conventional ingot manufacturing apparatus only including the upper heat shield, the narrow passage formed by the sweeping wall 320 may block the dust drawn into the growth zone (GZ).

In addition, vortex of the sweeping gas might be generated under the heat shield of the conventional ingot manufacturing apparatus.

However, the ingot manufacturing apparatus according to the present embodiment may include the sweeping wall 320 provided between the crucible 110 and the inner wall 120 to prevent such vortex of the sweeping gas (I).

The sweeping wall 320 may be arranged adjacent to the melting zone (MZ) such that the silicon melted in the melting zone (MZ) may keep the heat more effectively, compared with the conventional ingot manufacturing apparatus including only the upper heat shield.

A surface of the sweeping wall 320 may be formed of a material selected from the group consisting of SiC, SiN, SiCN, SiBN, SicBN, ZrC, ZrN, ZrCN, ZrBN, ZrcBN, TiC, TiN, TiCN, TiBN, TicBN, tungsten carbide, molybdenum (Mo), tungsten, tantalum or chrome.

For example, sweeping wall 320 may have graphite coated with a material selected from the group consisting of SiC, SiN, SiCN, SiBN, SicBN, ZrC, ZrN, ZrCN, ZrBN, ZrcBN, TiC, TiN, TiCN, TiBN and TicBN.

Alternatively, the sweeping wall may be formed of a material selected from the group consisting of SiC, SiCN, SiCN, SiBN, SicBN, ZrC, ZrN, ZrCN, ZrBN, ZrcBN, TiC, TiN, TiCN, TiBN TicBN and tungsten carbide.

The sweeping wall 320 may be formed of a material selected from the group consisting of molybdenum, tungsten and tantalum.

The sweeping wall 320 may be formed of a glass or quartz coated with chrome.

Accordingly, the surface of the sweeping wall 320 may reflect heat to keep the silicon melted in the inner wall 120 or the melting zone (MZ) hot.

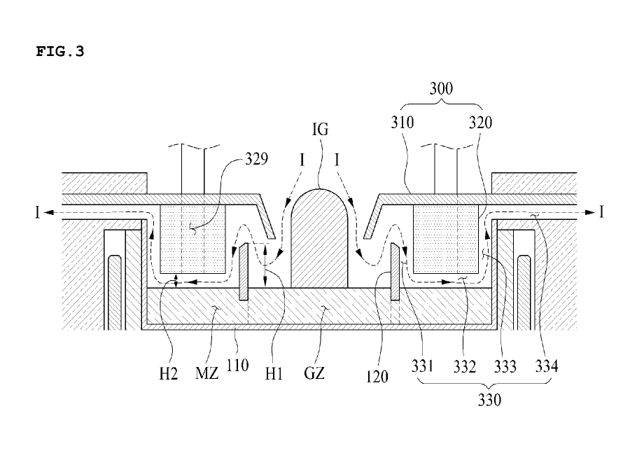

Referring to FIG. 3, the passage of the sweeping gas (I) transferred along the passage unit 300.

The passage unit 300 may include the upper heat shield 310 arranged in the upper portion of the melting zone (MZ) and the sweeping wall 320 to form the passage 330 in which the sweeping gas (I) is transferred along the surface of the melting zone (MZ) and the lateral surface of the crucible 110. The passage 330 may consist of a first part 331, a second part 332, a third part 333 and a fourth part 334.

The first part passage 331 may be formed between the inner wall 120 and the sweeping wall 320. The second part passage 332 may be formed between the surface of the melting zone (MZ) and the sweeping wall 320. The third part passage 333 may be formed between the sweeping wall 320 and the lateral surface of the crucible 110. The fourth part passage 334 may be formed between the upper heat shield 310 and an upper end of the crucible 110.

First of all, the sweeping gas (I) may be injected to a region where the ingot (IG) grows and block the dust from approaching the ingot (IG).

The sweeping gas (I) may pass the first part passage 331, the second part passage 332, the third part passage 333 and the fourth part passage 3334, to be exhausted outside the crucible 110.

In the ingot manufacturing apparatus according to the present embodiment, a cross sectional area of the passage of the sweeping gas (I) may be reduced by the passage unit 300. As the velocity of flowing sweeping gas (I) is getting fast, the dust inside the crucible 110 can be prevented from coming into the growth zone (GZ). The approach of the dust to the ingot (IG) is blocked and the ingot manufacturing process can be performed stably.

As the second part passage 332 is formed, the sweeping gas (I) may effectively remove the silicon oxide generated from a surface of the melting zone (MZ).

The sweeping wall 320 may be arranged adjacent to the inner wall 120 and a surface of the molten silicon in the melting zone (MZ), such that the molten silicon in the inner wall 120 and the melting zone (MZ) can keep the heat effectively.

The third part passage 333 may be narrower than or the same as the second part passage 332.

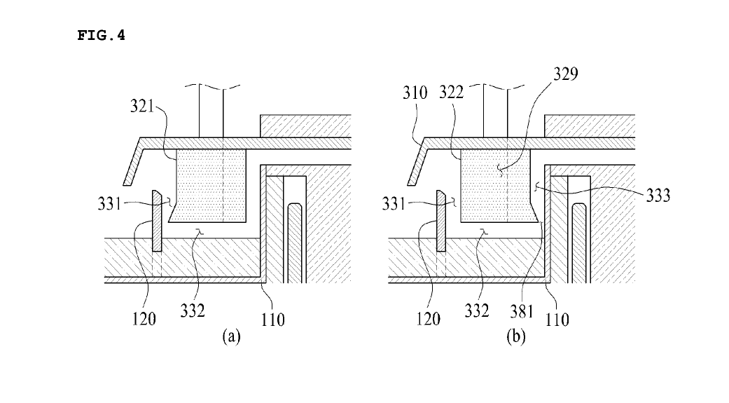

FIG. 4 is a diagram schematically illustrating an ingot manufacturing apparatus according to another embodiment of the disclosure. Elements with no descriptions in this embodiment are the same as the corresponding elements mentioned in the embodiment described above and the detailed descriptions will be omitted accordingly.

Referring to FIG. 4, a cross sectional area of a sweeping wall 321 applied to the present embodiment may be increased more and more along the downward direction. The cross sectional area of the sweeping wall 321 may be an area parallel to a surface of the melting zone (MZ) and the cross sectional area may mean a scalar quantity of the cross section.

The sweeping wall 321 shown in FIG. 4 (a) may be getting closer to the inner wall 120 along the downward direction. In other words, the first part passage 331 may be getting narrower along the direction in which the sweeping gas (I) is transferred.

In the ingot manufacturing apparatus according to the present embodiment of the disclosure, the first part passage 331 is getting narrower along the direction of the transferred sweeping gas (I) and the velocity of the sweeping gas flow can be increased.

Accordingly, the dust existing in the melting zone (MZ) may be prevented from approaching the growth zone (GZ) in which the ingot grows.

The sweeping wall 322 shown in FIG. 4 (b) may be getting closer to the crucible 110 in a downward direction. In other words, the sweeping wall 322 may increase the velocity of the sweeping gas flow as a boundary region 381 between the second part passage 332 and the third part passage 333 is getting narrower.

Accordingly, the dust inside the melting zone (MZ) can be transferred better to the third part passage 333 from the second part passage 332.

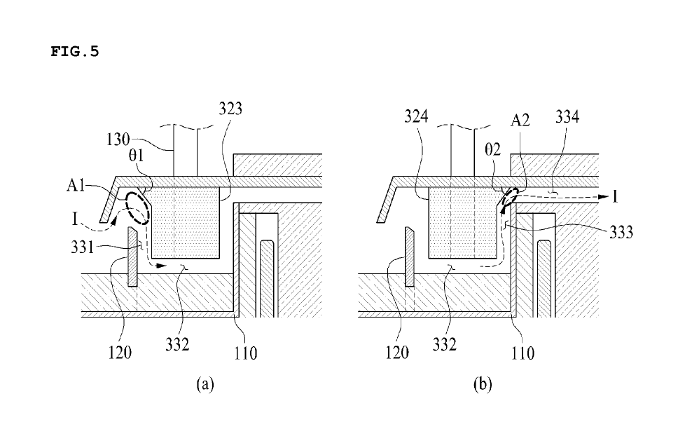

FIG. 5 is a diagram schematically illustrating an ingot manufacturing apparatus according to a further embodiment of the disclosure. Elements with no descriptions in this embodiment are the same as the corresponding elements mentioned in the embodiment described above and the detailed descriptions will be omitted accordingly.

Referring to FIG. 5, a cross sectional area of a sweeping wall 323 applied to the present embodiment may be increased more and more along an upward direction to the upper heat shield 310.

A side portion of the sweeping wall 323 toward the inner wall 120 may have a slope of an acute angle (θ1) with respect to a lower portion of the upper heat shield 310.

The portion having the slope of the acute angle (θ1) possessed by the sweeping wall 323 may prevent the vortex of the sweeping gas (I) introduced into the first part passage 331.

Also, the sweeping wall 323 may prevent the vortex of the sweeping gas (I) and results in preventing the dust or silicon from being deposited on a region (A2) provided between the upper heat shield 310 and the sweeping wall 323.

As shown in FIG. 5 (b), the other side portion of the sweeping wall 324 toward the crucible 110 may have a slope of an acute angle (θ2) with respect to the lower portion of the upper heat shield 310. Accordingly, the other side portion of the sweeping wall 324 having the slope of the acute angle (θ2) may prevent the vortex of the sweeping gas (I) introduced into the fourth part passage 331. Also, the sweeping wall 324 may prevent the vortex of the sweeping gas (I) and results in preventing the dust or silicon from being deposited on a region (A2) provided between the upper heat shield 310 and the sweeping wall 324.

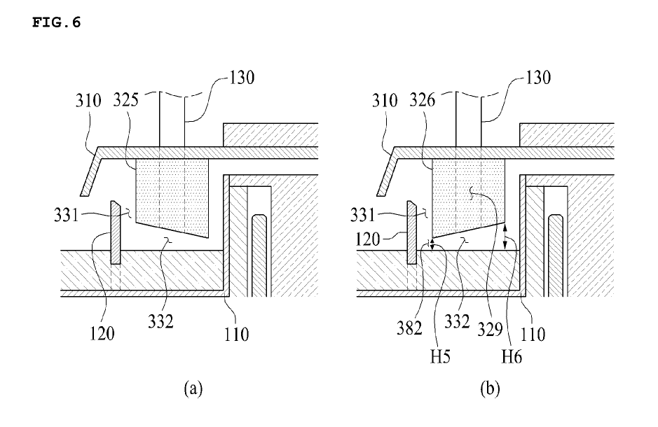

FIG. 6 is a diagram schematically illustrating an ingot manufacturing apparatus according to a still further embodiment of the disclosure. Elements with no descriptions in this embodiment are the same as the corresponding elements mentioned in the embodiment described above and the detailed descriptions will be omitted accordingly.

Referring to FIG. 6 (a), a lower end of a sweeping wall 325 may be getting closer to the melting zone (MZ) along a direction in which the sweeping gas (I) is transferred. In other words, the second part passage 332 may be getting narrower along the direction in which the sweeping gas (I) is transferred.

Accordingly, the velocity of the sweeping gas flow may be increased when the sweeping gas (I) is transferred along the second part passage 332.

Referring to FIG. 6 (b), a height (H5) to a lower end of the side portion of the sweeping wall 326 facing the inner wall 120 from a surface of the melting zone (MZ) is smaller than a height (H6) to a lower end of the other portion of the sweeping wall 326 facing the crucible 110 from a surface of the melting zone (MZ).

A boundary region 382 located between the first part passage 331 and the second part passage 332 may be getting narrower enough to increase the velocity of the flow in the boundary region 382. Accordingly, the dust located in the second part passage 332 may be prevented from being transferred to the first part passage 331 effectively.

An end of the feeding unit 130 and a lower end of the sweeping wall 326 may be located on the same plane, such that the end of the feeding unit 130 may not be projected more than the lower end of the sweeping wall 326. Accordingly, the end of the feeding unit 130 may not interfere with the transferring of the sweeping gas (I) through the second part passage 332.

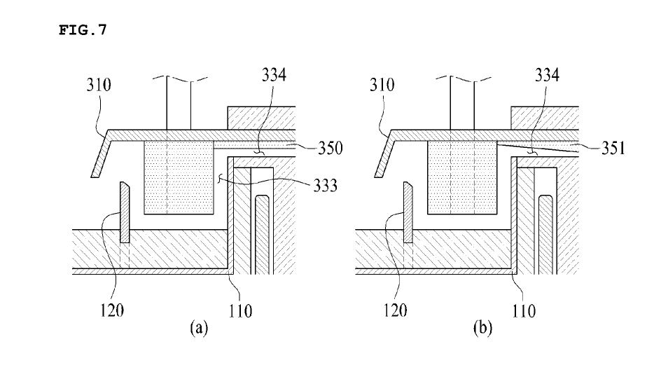

FIG. 7 is a diagram schematically illustrating an ingot manufacturing apparatus according to a still further embodiment of the disclosure. Elements with no descriptions in this embodiment are the same as the corresponding elements mentioned in the embodiment described above and the detailed descriptions will be omitted accordingly.

Referring to FIG. 7 (a), the passage unit 300 may further include an auxiliary sweeping wall 350 provided under the heat shield 110 in the fourth part passage 334. The auxiliary sweeping wall 350 may narrow the fourth part passage 334 than the third part passage 333, to increase the velocity of the sweeping gas passing through the fourth part passage 334.

The fourth part passage 334 may be getting narrower along a direction in which the sweeping gas (I) is transferred. Accordingly, the velocity of the sweeping gas (I) is increased in the fourth part passage 334 and the sweeping gas (I) can be transferred outside the crucible 110 smoothly.

Various variations and modifications of the embodiments described above are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. An apparatus for manufacturing an ingot, which supplies silicon intermittently or continuously while the ingot is growing, the apparatus comprising:
a crucible having a melting zone in which silicon melted;
an inner wall having a growth zone in which the ingot grows from the molten silicon supplied from the crucible;
a sweeping gas supply unit configured to supply sweeping gas to the growth zone; and
a passage unit configured to provide a passage of the sweeping gas transferred outside the crucible, the passage unit comprising an upper heat shield configured to cover an upper portion of the melting zone and a sweeping wall extended from the upper heat shield toward the melting zone in a downward direction.

2. The apparatus for manufacturing the ingot of claim 1, wherein the passage comprises,
a first part passage formed between the inner wall and the sweeping wall;
a second part passage formed between a surface of the melting zone and the sweeping wall;
a third part passage formed between the sweeping wall and the crucible; and
a fourth part passage formed between the upper heat shield and an upper end of the crucible.

3. The apparatus for manufacturing the ingot of claim 2, wherein the third part passage is smaller than or the same as the second part passage.

4. The apparatus for manufacturing the ingot of claim 1, wherein a cross sectional area of the sweeping wall is increased more and more along the downward direction.

5. The apparatus for manufacturing the ingot of claim 4, wherein the sweeping wall is getting closer to the inner wall along the downward direction.

6. The apparatus for manufacturing the ingot of claim 4, wherein the sweeping wall is getting closer to the crucible along the downward direction.

7. The apparatus for manufacturing the ingot of claim 1, wherein a cross sectional area of the sweeping wall is increased more and more along an upward direction to the upper heat shield.

8. The apparatus for manufacturing the ingot of claim 2, wherein the passage unit comprises an auxiliary sweeping wall provided under the upper heat shield in the fourth part passage.

9. The apparatus for manufacturing the ingot of claim 8, wherein the fourth part passage is getting narrower along a direction in which the sweeping gas is transferred.

10. The apparatus for manufacturing the ingot of claim 1, wherein a height to a lower end of the sweeping wall from a surface of melting zone is smaller than a height to an upper end of the inner wall from a surface of the melting zone.

11. The apparatus for manufacturing the ingot of claim 1, wherein a height to a lower end of the side portion of the sweeping wall facing the inner wall from a surface of the melting zone is larger than a height to a lower end of the other side portion of the sweeping wall facing the crucible from a surface of the melting zone.

12. The apparatus for manufacturing the ingot of claim 1, wherein a height to a lower end of the side portion of the sweeping wall facing the inner wall is smaller than a height to a lower end of the other side portion of the sweeping wall facing the crucible from a surface of the melting zone.

13. The apparatus for manufacturing the ingot of claim 1, further comprising:
a feeding unit configured to supply silicon to the melting zone via a silicon supply hole formed in the sweeping wall,
wherein an end of the feeding unit and a lower end of the sweeping wall are located on the same plane.

14. The apparatus for manufacturing the ingot of claim 1, wherein the sweeping wall is formed of a material selected from the group consisting of graphite, SiC, SiN, SiCN, SiBN, SicBN, ZrC, ZrN, ZrCN, ZrBN, ZrcBN, TiC, TiN, TiCN, TiBN, TicBN, molybdenum, tungsten and tantalum.

15. The apparatus for manufacturing the ingot of claim 1, wherein a surface of the sweeping wall is coated with a material selected from the group consisting of SiC, SiN, SiCN, SiBN, SicBN, ZrC, ZrN, ZrCN, ZrBN, ZrcBN, TiC, TiN, TiCN, TiBN and TicBN.

16. An apparatus for manufacturing an ingot, which supplies silicon intermittently or continuously while the ingot is growing, the apparatus comprising:
a crucible having a melting zone in which silicon melted;
an inner wall having a growth zone in which the ingot grows from the molten silicon supplied from the crucible;
a sweeping gas supply unit configured to supply sweeping gas to the growth zone; and
a passage unit comprising an upper heat shield configured cover an upper portion of the melting zone and a sweeping wall extended from the upper heat shield toward the melting zone in a downward direction, with a silicon supply hole configured to supply the silicon.

17. The apparatus for manufacturing the ingot of claim 16, wherein a height to a lower end of the sweeping wall is smaller than a height to an upper end of the inner wall from a surface of the melting zone.

18. The apparatus for manufacturing the ingot of claim 16, wherein a height to a lower end of the side portion of the sweeping wall facing the inner wall is larger than a height to a lower end of the other side portion of the sweeping wall facing the crucible from a surface of the melting zone.

19. The apparatus for manufacturing the ingot of claim 16, further comprising:
a feeding unit configured to supply silicon to the melting zone via the silicon supply hole formed in the sweeping wall,
wherein an end of the feeding unit and a lower end of the sweeping wall are located on the same plane.
